(19) United States
(12) Patent Application Publication
(10) Pub. No.: US 2008/0297988 A1
(43) Pub. Date: Dec. 4, 2008

(54) Interconnect module with integrated signal and power delivery

(75) Inventor: Danny Kwun-Man Chau, Fremont, CA (US)

Correspondence Address: Robert J. Kapalka;Tyco Electronics Corporation, Suite 140, 4550 New Linden Hill Road, Wilmington, DE, 19808-2952, US

(73) Assignee: Tyco Electronics Corporation

(21) Appl. No.: 11/809,320

(22) Filed: May 31, 2007

(51) Int. Cl. H05K 7/00

(52) U.S. Cl. 361/679

(57) ABSTRACT

An electrical connector assembly includes a first connector including a housing holding at least one power contact and at least one signal contact. The housing includes a guide post. The at least one signal contact includes an IDC terminating end for direct termination of a ribbon cable to the first connector. A second connector is matable to the first connector. The second connector includes a housing holding at least one power contact and at least one signal contact. The housing of the second connector includes a guide receptacle. The guide post and the guide receptacle cooperate to orient the first and second connectors to enable the first and second connectors to mate with one another.

### BACKGROUND OF THE INVENTION

The invention relates generally to electrical connectors and, more particularly, to an interconnect module with signal and power delivery.

Modern electronic systems such as telecommunications systems and computer systems often include large circuit boards called backplane boards which are rack mounted or retained in cabinets and are electrically connected to a number of smaller circuit boards called daughter cards. Electrical connectors establish communications between the backplane and the daughter cards. The daughter cards are typically separate from each other and meet different requirements for different purposes such as transmission of high speed signals, low speed signals, power, etc. that are transferred to the daughter cards from the backplane board.

In today's systems, there is a continuously increasing demand for resources, such as signal and power, and as a result, connector space on the circuit boards is in short supply. In many instances, due to space limitations, system operators limit the amount of connector space available for each application. Generally, separate connectors are used for power and signal transmission. With separate signal connectors and power connectors, the connectors are, at times, larger than need be for the amount of the particular resource, i.e. the amount of power or the number of signal lines, needed by the daughter card. Alternatively, some applications may have requirements for a particular resource, such as power, for instance, in an amount that cannot be accommodated with the connectors readily available that can fit into the allotted space.

A need exists for a connector that is configurable to provide multiple types of resources such as signal and power transmission in the same connector. A further need exists for a connector that is configurable to meet particular resource requirements such as voltage, current, or separation space. It would also be advantageous if a given resource could be placed in a designated location within the connector.

### BRIEF DESCRIPTION OF THE INVENTION

In one embodiment, an electrical connector assembly is provided. The assembly includes a first connector including a housing holding at least one power contact and at least one signal contact. The housing includes a guide post. The at least one signal contact includes an IDC terminating end for direct termination of a ribbon cable to the first connector. A second connector is matable to the first connector. The second connector includes a housing holding at least one power contact and at least one signal contact. The housing of the second connector includes a guide receptacle. The guide post and the guide receptacle cooperate to orient the first and second connectors to enable the first and second connectors to mate with one another.

Optionally, the second connector includes a mounting portion, a mating portion, and a contact retention clip held between the mounting and mating portions. The clip has an edge that engages a step on the mounting portion and a tab that engages a step on the at least one power contact in the second connector. The at least one power contacts include first power contacts and second power contacts. The first power contacts are configured to carry a first current and the second power contacts are configured to carry a second current different from the first current. The at least one power contact in the second connector includes a mating end that extends through an interior wall of the mating portion of the second connector.

In another embodiment, an electrical connector assembly includes a first connector including a housing holding at least one power contact and at least one signal contact. The at least one signal contact includes a stabilizing arm and a stabilizing plate to position and stabilize the at least one signal contact in the housing, and an IDC terminating end for direct termination of a ribbon cable to the first connector. A second connector includes a housing holding at least one power contact and at least one signal contact. The second connector includes a mating portion that is matable to the first connector and a mounting portion configured to be mounted to a power supply.

### BRIEF DESCRIPTION OF THE DRAWINGS

FIG. 1 is a perspective view of a mated connector assembly formed in accordance with an exemplary embodiment of the present invention.

FIG. 2 is a perspective view of the first connector shown in FIG. 1.

FIG. 3 is an exploded view of the first connector shown in FIG. 1 taken from the mounting face.

FIG. 4 is a perspective view of an exemplary signal contact.

FIG. 5 is a perspective view of the second connector shown in FIG. 1 taken from the mounting face.

FIG. 6 is a perspective view of the second connector shown in FIG. 1 taken from the mating face.

FIG. 7 is a cross-sectional view of the second connector taken along the line 7-7 in FIG. 6.

FIG. 8 is an exploded view of the second connector shown in FIGS. 5 and 6.

FIG. 9 is a perspective view of an exemplary contact retention clip.

### DETAILED DESCRIPTION OF THE INVENTION

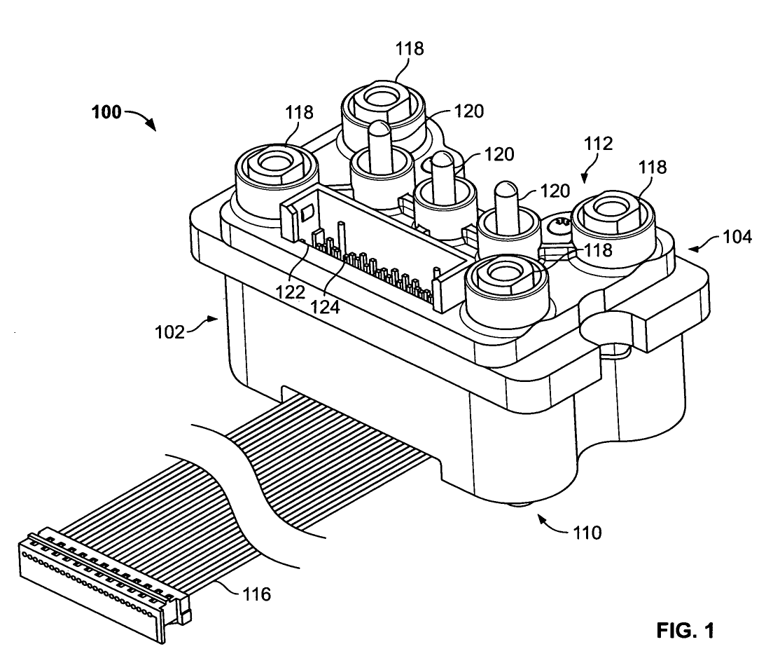

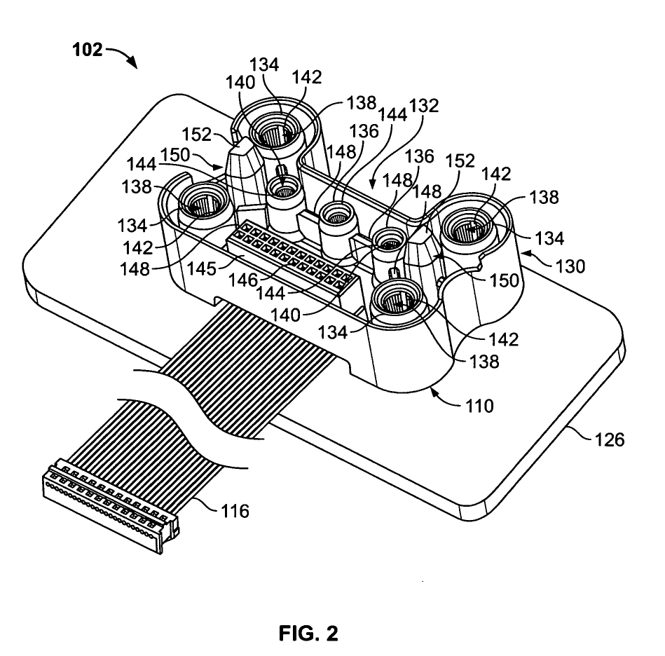

FIG. 1 illustrates a perspective view of a mated connector assembly 100 formed in accordance with an exemplary embodiment of the present invention. The assembly 100 includes a first connector 102 and a mating second connector 104. The first connector 102 may be a socket connector 102 and the second connector 104 may be a mating pin connector 104. The assembly 100 integrates power and signal delivery to an electrical system. The first connector 102 includes a mounting face 110. The second connector has a mounting face 112. The assembly 100 will be described in terms of an assembly wherein the first connector 102 is mounted on a backplane or midplane (see FIG. 2) and the second connector 104 is mounted on or connected to a power supply (not shown). It is to be understood; however, that the benefits of the invention may be realized in any application where integrated power and signal delivery is desirable, such as, for instance to save space on the electrical system.

Signal information is delivered to the electrical system from the first connector 102 via a multi-conductor ribbon cable 116. Power output is provided to the system via power contacts (not shown in FIG. 1) from the mounting face 110 of the first connector 102 as will be described. Power from the power supply is received into the second connector 104 through terminations to first power contacts 118 and second power contacts 120 on the mounting face 112. Signal information is received into the second connector 104 through a ribbon cable connector receptacle 122 that includes signal contact pins 124. The first power contacts 118 are sized larger than the second power contacts 120. Consistent with the relative sizes of the contacts 118 and 120, the first power contacts 118 are sized to carry a first current level while the second power contacts 120 are sized to carry a second current level that is different from, and more specifically, less than the first current level, such that power may be delivered to the electrical system at least at two different current levels.

FIG. 2 illustrates a perspective view of the first connector 102 mounted on a circuit board 126 to provide power and signal information to an electrical system. The circuit board 126 may be a midplane board or a backplane board. The first connector 102 includes a one piece dielectric housing 130 that has a mating face 132 opposite the mounting face 110. Contact apertures 134 and 136 are formed on the mating face 132. First power contacts 138 and second power contacts 140 are held in the housing 130. The first power contacts 138 and second power contacts 140 have mating ends 142 and 144, respectively that are configured to receive a correspondingly sized pin contacts. In one embodiment, the first power contacts 138 and second power contacts 140 are press fit into the housing 130. The first power contacts 138 are larger than the second power contacts 140 and have a higher current carrying capacity than the second power contacts 140 such that power may be delivered to the electrical system at least at two different current levels. The housing 130 includes a signal contact mating portion 145 that includes a plurality of substantially square signal pin contact apertures or cavities 146. The contact cavities 146 are provided for making electrical connections to the ribbon cable 116. The housing 130 is formed with a plurality of ridges 148 that extend between the contact apertures 134 and 136.

A pair of guide posts 150 are molded on the housing 130 and extend from the mating face 132. Each guide post 150 has a tapered tip 152 to facilitate blind mating with the second connector 104 (FIG. 1). As illustrated in FIG. 2, the guide posts are formed with a D-shaped cross section and are configured to be received in guide channels in the second connector 104 that are complementary in shape. The guide posts are oriented relative to one another so that the second connector 104 is matable with the first connector 102 in only one way, so that the connector assembly 100 is a polarized assembly. Since the connector assembly 100 is a multiple contact system having contacts operating at different voltages, the polarization feature is an important feature of the invention. It is important that the first connector 102 and the second connector 104 be properly oriented with respect to one another before an electrical connection is made with any of the contacts in the connector assembly 100. It is contemplated that the guide posts 150 may be formed with cross sections having other geometric shapes while preserving the polarization feature.

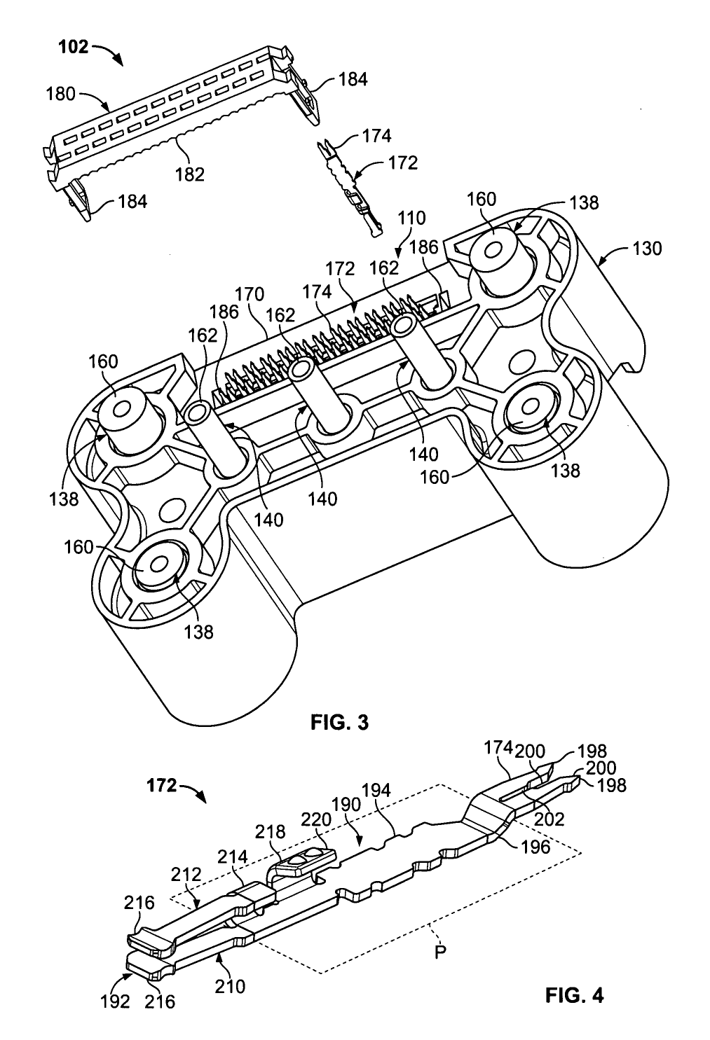

FIG. 3 illustrates an exploded view of the first connector 102 showing the mounting face 110. The first power contacts 138 have mounting ends 160 and the second power contacts 140 have mounting ends 162. In an exemplary embodiment, the mounting ends 160 and 162 are threaded for a threaded attachment to the midplane or backplane 126 (FIG. 2). As illustrated, first connector 102 holds seven power contacts 138, 140. However, the number of contacts may be varied based on the requirements of the electrical system. More generally, the first connector 102 and second connector 104 (FIG. 1) are configurable to meet the resource requirements of a particular electrical system. Further, the power contacts 138, 140 may be placed in designated locations or arranged within the connectors 102 and 104 to also meet system requirements. Fewer power contacts 138, 140 may be utilized when, for instance, more separation space is desired between the contacts 138, 140. The power contacts 138 and 140 may be any of several socket contact designs well known in the art having threaded mounting ends.

The first connector 102 includes a lacing area 170 proximate the mating face 110 for terminating the signal cable 116 (FIG. 2) to signal contacts 172. The signal contacts 172 are arranged in two rows and include insulation displacement contact (IDC) terminating ends 174 that extend to the lacing area 170. The IDC terminating ends 174 facilitate direct termination of the ribbon cable 116 to the first connector 102. The signal contacts 172 are press fit into the housing 130. An insulative cover 180 covers the signal contact lacing area 170. A plurality of ribs 182 are provided on an underside of the cover 180 to grip and arrange the individual wires of the signal cable 116 during the termination process. The cover 180 includes a pair of latch arms 184 that are received in pockets 186 in the housing 130. When the signal cable 116 is positioned in the lacing area 170, installation of the cover 180 drives the cable wires into the IDC terminating ends 174 to complete the signal contact termination process. In one embodiment, the latch arms 184 are received in the pockets 186 with a snap fit.

FIG. 4 illustrates a perspective view the signal contact 172. In the exemplary embodiment, the signal contact 172 is stamped and formed from a metallic material and includes a substantially planar contact body 190 between the terminating end 174 and an opposite mating end 192. The body 190 has a mounting section 194 that frictionally engages the housing 130 to hold the contact 172 in the housing 130. An offset section 196 offsets the terminating end 174 from a plane P in which the body 190 lies. The terminating end 174 includes insulation piercing tips 198 and cutting edges 200. A slot 202 receives and holds an individual wire of the ribbon cable 116 (FIG. 2) in electrical engagement therewith to terminate the wire to the contact 172. The mating end 192 includes opposed contact beams 210 and 212. The contact beam 212 extends from an arcuate section 214 that joins the contact beam 212 to the body 190. Each contact beam 210, 212 is formed with an outwardly turned contact tip 216 to receive a mating contact (not shown). An arcuate stabilizing arm 218 extends from the contact body 190 and terminates in a stabilizing plate 220. The stabilizing arm 218 and stabilizing plate 220 are provided to position and stabilize the contact 172 in the square contact cavities 146 (FIG. 2).

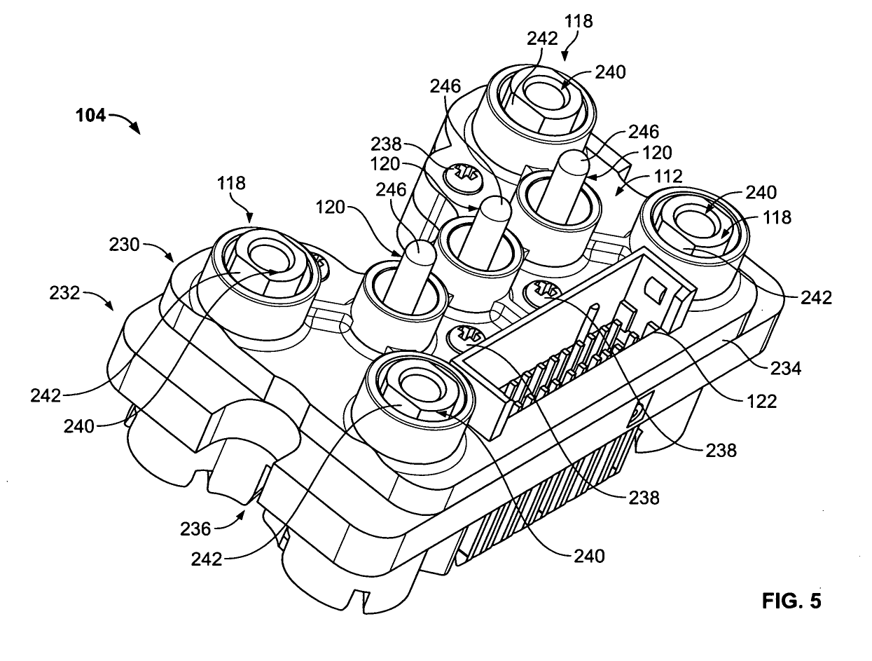

FIG. 5 illustrates a perspective view of the second connector 104. The second connector 104 is a two-piece assembly including a mounting portion 230 and a mating portion 232. The mounting portion 230 includes a housing 234 that includes the mounting face 112. The mating portion 232 includes a mating face 236 that mates with the mating face 132 of the first connector 102 (FIG. 2). Threaded fasteners 238 hold the portions 230 and 232 together. In an exemplary embodiment, the second connector 104 is mounted on a power supply. The first power contacts 118 include mounting ends 240 that are configured for threaded termination to a wire. Flats 242 are provided on the mounting ends 240 so that the contacts may be held to prevent rotation of the first power contacts 118 during termination. The second power contacts 120 include solder tail mounting ends 246. The signal cable connector receptacle 122 is configured to receive a standard ribbon cable connector.

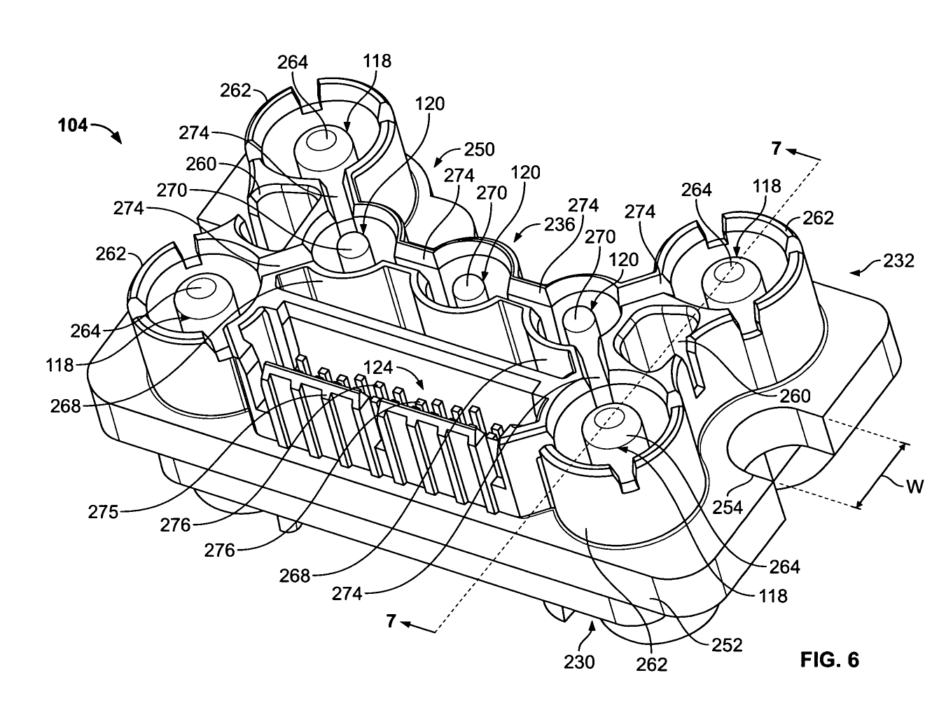

FIG. 6 illustrates a perspective view of the second connector 104 from the mating face 236 of the mating portion 232. The mating portion 232 includes a housing 250 having a mounting flange 252 configured for mounting the second connector 104 to a power supply (not shown). The mounting flange 252 includes cutouts 254 that are configured to accept shoulder type mounting screws (not shown). In an exemplary embodiment, the mounting screws have a diameter that is less than a width W of the cutouts 254 so that the second connector 104 can float to facilitate blind mating with the first connector 102 (FIG. 2). More specifically, the mounting flange 252 with the cutouts 254 cooperate with the tapered tips 152 of the guide posts 150 (FIG. 2) to facilitate blind mating of the second connector 104 with the first connector 102.

Guide receptacles 260 are formed on the housing 250. The guide receptacles 260 are configured to receive the guide posts 150 on the first connector 102 (FIG. 2) to orient the second connector 104 and first connector 102 with respect to one another prior to any electrical connection being made between the connectors 104 and 102. That is, the guide receptacles 260 and the guide posts 150 cooperate to orient the connectors 102 and 104 so as to enable the connectors 102 and 104 to mate with one another. The housing 250 includes shrouds 262 that surround mating ends 264 of the first power contacts 118. Similarly, shrouds 268 are formed around mating ends 270 of the second power contacts 120. A plurality of channels 274 extend between the shrouds 262 and 268 that receive the ribs 148 on the housing 130 (FIG. 2) when the second connector 104 is mated with the first connector 102. A signal contact shroud 275 surrounds the signal contact pins 124 and is sized to receive the signal contact mating portion 145 (FIG. 2) of the housing 130. The contact pins 124 include mating ends 276 that are configured to be received in the signal pin contact apertures 146 (FIG. 2) to deliver signal information to the first connector 102. The mating ends 276 of the signal contact pins 124 may be varied in length for sequenced mating of the signal contact pins 124 with the signal contacts 272 (FIG. 3) in the first connector 102. In a similar manner, the mating ends 264 and 270 of the first and second power contacts 118 and 120, respectively, may also be varied in length where sequenced mating of the power contacts 118 and 120 is desired.

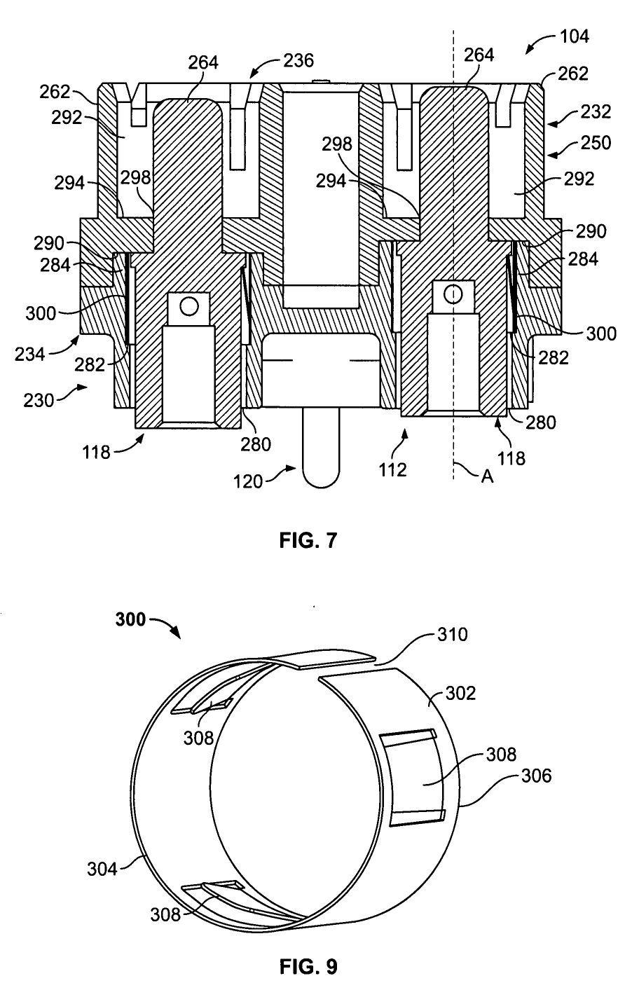

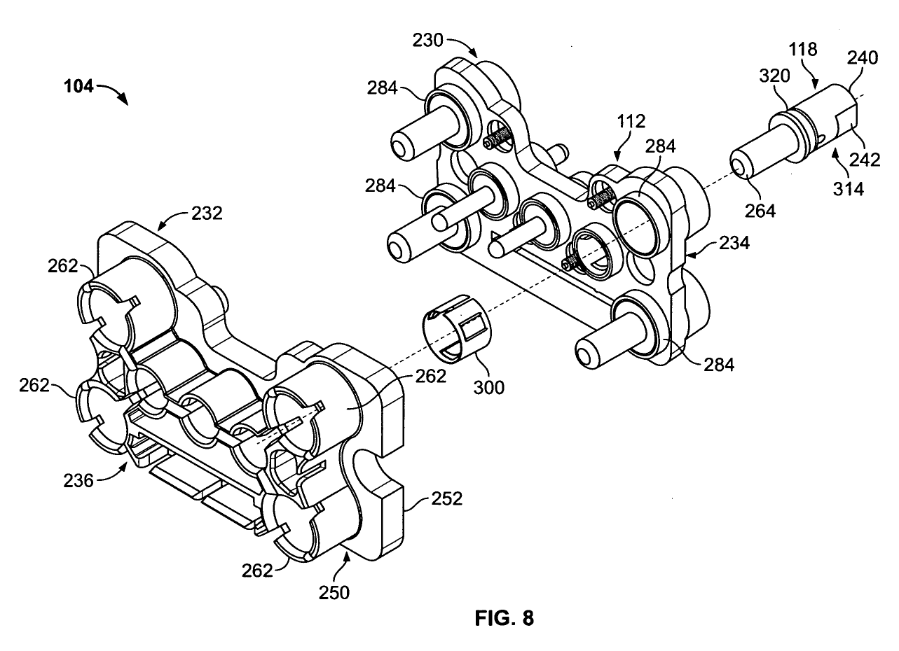

FIG. 7 illustrates a cross-sectional view of the second connector 104 taken along the line 7-7 in FIG. 6. FIG. 8 illustrates an exploded view of the second connector 104. FIG. 9 illustrates a perspective view of an exemplary retention clip 300. The mounting portion 230 includes contact cavities 280 that receive the first power contacts 118. Although not shown in detail in FIG. 7, the second power contacts 120 are held in contact cavities similar in structure to the contact cavities 280. The contact cavities 280 have a centerline A and are counterbored to produce a step 282 that faces the mating portion 232. Cylindrical extensions 284 of the walls of the contact cavities 280 extend into the mating portion 232.

For each first power contact 118, the mating portion 232 defines a first cavity 290 and a second cavity 292, both of which are aligned along the centerline A. The second cavity 292 is within the shroud 262. An interior wall 294 separates the first and second cavities 290 and 292 and includes an opening 298 sized to receive the mating end 264 of the first power contact 118. The extension 284 abuts the interior wall 294. A retention clip 300 holds the first power contact 118 in the housing 234. Similar retention clips (not shown) are provided to hold the second power contacts 120 in the housing 234. The retention clip 300 is generally cylindrical in shape and includes a band 302 of a flexible material that has a first edge 304 and a second edge 306. A plurality of flexible tabs 308 are formed around the band. The tabs 308 are biased toward the interior of the band 302. The band 302 includes a gap 310 that allows the band to be compressed when inserted into the housing 230.

The first power contact 118 includes a substantially cylindrical contact body 314 that has a step 320 formed between the mounting end 240 and the mating end 264. When the connector 104 is assembled, the retention clip 300 is inserted into the contact cavity 280 from the mounting face 112 until it abuts the interior wall 294 of the housing 234 at which point, the retention clip 300 snaps over the step 282. The retention clip 300 is held between the housing 234 of the mounting portion 230 and the housing 250 of the mating portion 232. Once the clip 300 is inserted, the first edge 304 engages the interior wall 294 in the mating portion 232 and the second edge 306 engages the step 282 in the mounting portion 230. The first power contact 118 is then inserted into the contact cavity 280 and through the clip 300, also from the mounting face 112, until the flexible tabs 308 snap over and engage the step 320 on the first power contact 118 to retain the contact 118 in the connector 104. The second power contacts 120 are loaded into and retained in the connector 104 in a similar manner.

The embodiments thus described provide an integrated power and signal interconnect assembly that provides both signal and power resources to an electrical system. The assembly includes pin and socket connectors that utilize guide pins to polarize or orient the connectors with respect to one another. The socket connector includes a one piece IDC contact that allows a ribbon type signal cable to be terminated directly to the socket connector. The assembly also facilitates blind mating and sequenced mating of the signal and power contacts.

While the invention has been described in terms of various specific embodiments, those skilled in the art will recognize that the invention can be practiced with modification within the spirit and scope of the claims.

What is claimed is:

1. An electrical connector assembly comprising:
a first connector including a housing holding at least one power contact and at least one signal contact, said housing including a guide post, wherein said at least one signal contact includes an IDC terminating end for direct termination of a ribbon cable to said first connector; and
a second connector matable to said first connector, said second connector including a housing holding at least one power contact and at least one signal contact, said housing of said second connector including a guide receptacle, and wherein said guide post and said guide receptacle cooperate to orient said first and second connectors to enable the first and second connectors to mate with one another.

2. The electrical connector assembly of claim 1, wherein said first connector includes a lacing area and a cover over said lacing area, said cover including a plurality of ribs configured to grip and arrange the individual wires of the ribbon cable.

3. The electrical connector assembly of claim 1, wherein said second connector comprises a mounting portion, a mating portion, and a contact retention clip held between said mounting and mating portions.

4. The electrical connector assembly of claim 1, wherein said second connector comprises a mounting portion, a mating portion, and a contact retention clip held between said mounting and mating portions, said clip having an edge that engages a step on said mounting portion and a tab that engages a step on said at least one power contact in said second connector.

5. The electrical connector assembly of claim 1, wherein said at least one power contacts include first power contacts and second power contacts, and wherein the first power contacts are configured to carry a first current and the second power contacts are configured to carry a second current different from the first current.

6. The electrical connector assembly of claim 1, wherein said guide post includes a tapered tip and said second connector includes a mounting flange configured to mount said second connector to a power supply such that limited movement with respect to the power supply is enabled and wherein said tapered tip cooperates with said mounting flange to enable blind mating of said first connector with said second connector.

7. The electrical connector assembly of claim 1, wherein said housing of said first connector includes a mating face having a plurality of ridges and said housing of said second connector includes a mating face having a plurality of channels that receive said plurality of ridges when said first and second connectors are mated with one another.

8. The electrical connector assembly of claim 1, wherein said second connector includes a mating portion and a mounting portion having a receptacle configured to receive a ribbon cable connector.

9. The electrical connector assembly of claim 1, wherein said second connector includes a mating portion and a mounting portion, said at least one power contact in said second connector including a mating end that extends through an interior wall of said mating portion.

10. An electrical connector assembly comprising:
a first connector including a housing holding at least one power contact and at least one signal contact, said at least one signal contact including a stabilizing arm and a stabilizing plate to position and stabilize said at least one signal contact in said housing, and an IDC terminating end for direct termination of a ribbon cable to said first connector; and
a second connector including a housing holding at least one power contact and at least one signal contact, said second connector including a mating portion that is matable to said first connector and a mounting portion configured to be mounted to a power supply.

11. The electrical connector assembly of claim 10, wherein said at least one signal contact in said first connector includes a mating end, a body, and a terminating end that is offset out of a plane of said body.

12. The electrical connector assembly of claim 10, wherein said housing of said first connector includes a guide post and said second connector includes a guide receptacle, and wherein said guide post and said guide receptacle cooperate to orient said first and second connectors to enable the first and second connectors to mate with one another.

13. The electrical connector assembly of claim 10, wherein said first connector includes a lacing area and a cover over said lacing area, said cover including a plurality of ribs configured to grip and arrange the individual wires of the ribbon cable.

14. The electrical connector assembly of claim 10, wherein said second connector includes a contact retention clip held between said mounting and mating portions.

15. The electrical connector assembly of claim 10, wherein said second connector includes a contact retention clip held between said mounting and mating portions, said clip having an edge that engages a step on said mounting portion and a tab that engages a step on said at least one power contact in said second connector.

16. The electrical connector assembly of claim 10, wherein said at least one power contacts include first power contacts and second power contacts, and wherein the first power contacts are configured to carry a first current and the second power contacts are configured to carry a second current different from the first current.

17. The electrical connector assembly of claim 10, wherein said housing of said first connector includes a guide post having a tapered tip and said second connector includes a mounting flange configured to mount said second connector to a power supply such that limited movement with respect to the power supply is enabled and wherein said tapered tip cooperates with said mounting flange to enable blind mating of said first connector with said second connector.

18. The electrical connector assembly of claim 10, wherein said housing of said first connector includes a mating face having a plurality of ridges and said housing of said second connector includes a mating face having a plurality of channels that receive said plurality of ridges when said first and second connectors are mated with one another.

19. The electrical connector assembly of claim 10, wherein said mounting portion of second connector includes a receptacle configured to receive a ribbon cable connector.

20. The electrical connector assembly of claim 10, wherein said at least one power contact in said second connector including a mating end that extends through an interior wall of said mating portion.
